(19) United States
(12) Patent Application Publication
(10) Pub. No.: US 2012/0240857 A1
(43) Pub. Date: Sep. 27, 2012

(54) VERTICAL HEAT TREATMENT APPARATUS

(75) Inventors: Yuichiro Morozumi, Yamanashi (JP); Izumi Sato, Iwate (JP)

(73) Assignee: Tokyo Electron Limited, Tokyo (JP)

(21) Appl. No.: 13/239,541

(22) Filed: Sep. 22, 2011

(30) Foreign Application Priority Data
Sep. 29, 2010 (JP) 2010-219726

(51) Int. Cl. C23C 16/46

(52) U.S. Cl. 118/725

(57) ABSTRACT

A vertical heat treatment apparatus includes a reaction tube surrounded by a heating part and including a substrate holder to hold substrates; and a process gas feed part having gas ejection openings to feed a process gas onto the substrates. The reaction tube has an exhaust opening at a position opposite to the gas ejection openings relative to the center of the reaction tube. The substrate holder includes circular holding plates stacked in layers and each having substrate placement regions; and support rods supporting the holding plates and provided in a circumferential direction of the holding plates to penetrate through the holding plates with the outside positions of the support rods being at the same radial position as the outer edges of the holding plates or at a radial position inside the outer edges of the holding plates relative to the center of the reaction tube.

### CROSS-REFERENCE TO RELATED APPLICATIONS

The present application is based upon and claims the benefit of Japanese Patent Application No. 2010-219726, filed on Sep. 29, 2010, the entire contents of which are incorporated herein by reference.

### BACKGROUND OF THE INVENTION

1. Field of the Invention

The present invention relates to a vertical heat treatment apparatus configured to perform heat treatment on multiple substrates loaded into a substrate holder in multiple stages by feeding a process gas.

2. Description of the Related Art

As a heat treatment apparatus to perform heat treatment such as a film deposition process on a substrate such as a semiconductor wafer (hereinafter referred to as “wafer”), a batch-type vertical heat treatment apparatus is known that loads a wafer boat, which is a substrate holder, with multiple wafers in multiple stages, accommodates this wafer boat in a reaction tube in an airtight manner, and feeds a process gas into the reaction tube in a vacuum atmosphere, thereby depositing thin films. This wafer boat has a disk-shaped top plate, a disk-shaped bottom plate, and support rods that are attached to the top plate and the bottom plate from their periphery sides at circumferentially spaced apart multiple points to connect the top plate and the bottom plate. Multiple slit-shaped grooves are so formed on the side surfaces of the support rods at intervals in a vertical direction as to face a region for receiving wafers. The wafers are received with their respective end portions supported in these grooves of the support rods. In the space between the peripheral portions of the wafers supported in the wafer boat and the inner wall of the reaction tube, gap regions are so formed in a circumferential direction as to correspond to regions where the support rods are provided.

As a method of feeding a process gas into this reaction tube, a cross-flow system may be employed so that a gas flow is formed horizontally on each wafer as illustrated in Japanese Laid-Open Patent Application No. 2009-206489. Specifically, for example, with a reaction tube having a double-tube structure of an inner tube and an outer tube, a vertically elongated slit-shaped exhaust opening is formed in the inner tube, and a vertically extending gas injector is so placed beside a wafer boat as to face the exhaust opening. Multiple gas ejection openings are so formed in the side wall of the gas injector as to correspond to the vertical positions of wafers, so that a gas flow heading from the gas ejection opening to the exhaust opening is formed on each wafer.

At this point, gap regions are formed in a circumferential direction between the peripheral portions of the wafers supported in the wafer boat and the reaction tube (inner tube) as described above. As a result of this configuration, the process gas ejected from the gas injector tends to flow more through these gap regions than through narrow regions between the wafers. This decreases the amount of gas fed to the wafers through the narrow regions between the wafers, thus reducing the efficiency of use of the process gas.

Japanese Laid-Open Patent Application No. 2010-73823 and Japanese Laid-Open Patent Application No. 61-136676 describe the techniques of circumferentially arranging wafers on a wafer disk or susceptor, and Japanese Laid-Open Patent Application No. 2000-208425 describes an apparatus that performs processing with wafers vertically stacked in layers. However, no description is given of the above-mentioned problem.

### SUMMARY OF THE INVENTION

According to an aspect of the present invention, a vertical heat treatment apparatus includes a vertical reaction tube including a substrate holder and surrounded by a heating part, the substrate holder being configured to hold a plurality of substrates in multiple stages and to perform heat treatment on the substrates; and a process gas feed part provided in a lengthwise direction of the reaction tube and having a plurality of gas ejection openings formed at vertical positions corresponding to the respective substrates to feed a process gas onto the substrates held in the substrate holder, wherein the reaction tube has an exhaust opening formed therein at a position opposite to the gas ejection openings relative to a center of the reaction tube, and the substrate holder includes a plurality of circular holding plates stacked in layers at intervals and each having a plurality of substrate placement regions formed thereon; and a plurality of support rods supporting the holding plates, the support rods being provided in a circumferential direction of the holding plates to penetrate through the holding plates with outside positions of the support rods being at a same radial position as outer edges of the holding plates or at a radial position inside the outer edges of the holding plates relative to the center of the reaction tube.

According to an aspect of the present invention, a vertical heat treatment apparatus includes a vertical reaction tube including a substrate holder and surrounded by a heating part, the substrate holder being configured to hold a plurality of substrates in multiple stages and to perform heat treatment on the substrates; and a process gas feed part provided in a lengthwise direction of the reaction tube and having a plurality of gas ejection openings formed at vertical positions corresponding to the respective substrates to feed a process gas onto the substrates held in the substrate holder, wherein the reaction tube has an exhaust opening formed therein at a position opposite to the gas ejection openings relative to a center of the reaction tube, the substrate holder includes a plurality of circular holding plates stacked in layers at intervals and each having a substrate placement region formed thereon; and a plurality of support rods supporting the holding plates, the support rods being provided in a circumferential direction of the holding plates to penetrate through the holding plates with outside positions of the support rods being at a same radial position as outer edges of the holding plates or at a radial position inside the outer edges of the holding plates relative to the center of the reaction tube, and a clearance between the outer edges of the holder plates and an inner wall surface of the reaction tube is smaller than a clearance between an upper surface of the substrate supported on a first one of the holding plates and a lower surface of a second one of the holding plates immediately above and opposite the first one of the holding plates.

According to an aspect of the present invention, a vertical heat treatment apparatus includes a vertical reaction tube including a substrate holder and surrounded by a heating part, the substrate holder being configured to hold a plurality of substrates in multiple stages and to perform heat treatment on the substrates; and a process gas feed part provided in a lengthwise direction of the reaction tube and having a plurality of gas ejection openings formed at vertical positions corresponding to the respective substrates to feed a process gas onto the substrates held in the substrate holder, wherein the reaction tube has an exhaust opening formed therein at a position opposite to the gas ejection openings relative to a center of the reaction tube, and the substrate holder includes a plurality of circular holding plates stacked in layers at intervals and each having a plurality of substrate placement regions formed thereon; and a plurality of support rods supporting the holding plates, the support rods being provided in a circumferential direction of the holding plates to penetrate through the holding plates with outside positions of the support rods being at or inside positions 3 mm outward relative to outer edges of the holder plates in a radial direction of the reaction tube.

### BRIEF DESCRIPTION OF THE DRAWINGS

Accompanying drawings, which are incorporated in and constitute a part of the specification, illustrate embodiments of the invention, and together with the general description given above and the detailed description of the embodiments given below, serve to explain the principles of the invention, in which:

FIG. 1 is a lengthwise cross-sectional view of a vertical heat treatment apparatus according to an embodiment of the present invention;

FIG. 2 is a crosswise cross-sectional view of the vertical heat treatment apparatus according to the embodiment of the present invention;

FIG. 3 is an enlarged view of part of the vertical heat treatment apparatus according to the embodiment of the present invention;

FIG. 4 is a crosswise cross-sectional view of the vertical heat treatment apparatus according to the embodiment of the present invention, illustrating an operation of the vertical heat treatment apparatus;

FIG. 5 is an enlarged view of part of the vertical heat treatment apparatus according to the embodiment of the present invention, illustrating the operation of the vertical heat treatment apparatus;

FIG. 6 is a crosswise cross-sectional view of the vertical heat treatment apparatus according to the embodiment of the present invention, illustrating the operation of the vertical heat treatment apparatus;

FIG. 7 is a crosswise cross-sectional view of the vertical heat treatment apparatus according to the embodiment of the present invention, illustrating the operation of the vertical heat treatment apparatus;

FIG. 8 is a crosswise cross-sectional view of the vertical heat treatment apparatus according to the embodiment of the present invention, illustrating the operation of the vertical heat treatment apparatus;

FIG. 9 is a crosswise cross-sectional view of part of an example of the vertical heat treatment apparatus according to the embodiment of the present invention;

FIG. 10 is a crosswise cross-sectional view of part of another example of the vertical heat treatment apparatus according to the embodiment of the present invention;

FIG. 11 is a lengthwise cross-sectional view of another example of the vertical heat treatment apparatus according to the embodiment of the present invention;

FIG. 12 is a perspective view of a reaction tube of the example of the vertical heat treatment apparatus of FIG. 11 according to the embodiment of the present invention; and

FIG. 13 is a crosswise cross-sectional view of part of another example of the vertical heat treatment apparatus according to the embodiment of the present invention.

### DETAILED DESCRIPTION OF THE PREFERRED EMBODIMENTS

### Introduction

As a heat treatment apparatus that performs heat treatment such as a film deposition process on wafers, a batch-type vertical heat treatment apparatus is known that loads a wafer boat with approximately 100 to approximately 150 wafers in multiple stages, accommodates this wafer boat in a reaction tube in an airtight manner, and feeds a process gas into the reaction tube in a vacuum atmosphere, thereby depositing thin films. This wafer boat has a disk-shaped top plate, a disk-shaped bottom plate, and support rods that are attached to the top plate and the bottom plate from their periphery sides at circumferentially spaced apart multiple points to connect the top plate and the bottom plate. Multiple slit-shaped grooves are so formed on the side surfaces of the support rods at intervals in a vertical direction as to face a region for receiving wafers. The wafers are received with their respective end portions supported in these grooves of the support rods. In the space between the peripheral portions of the wafers supported in the wafer boat and the inner wall of the reaction tube, gap regions are so formed in a circumferential direction as to correspond to regions where the support rods are provided.

As a method of feeding a process gas into this reaction tube, a cross-flow system may be employed. Specifically, for example, with a reaction tube having a double-tube structure of an inner tube and an outer tube, a vertically elongated slit-shaped exhaust opening is formed in the inner tube, and a vertically extending gas injector is so placed beside a wafer boat as to face the exhaust opening. Multiple gas ejection openings are so formed in the side wall of the gas injector as to correspond to the vertical positions of wafers, so that a gas flow heading from the gas ejection opening to the exhaust opening is formed on each wafer.

At this point, gap regions are formed in a circumferential direction between the peripheral portions of the wafers supported in the wafer boat and the reaction tube (inner tube) as described above. As a result of this configuration, the process gas ejected from the gas injector tends to flow more through these gap regions than through narrow regions between the wafers. This causes the amount of gas fed to the wafers through the narrow regions between the wafers to be less than a set value, so that the degradation of productivity (film deposition rate) and of the uniformity of film thickness and a coverage characteristic in the plane may be caused. Further, the discharge of a process gas without contribution to film deposition increases the amount of use of the process gas, thus causing an increase in cost.

In recent years, consideration has been given to a process of depositing, for example, an alumina (Al₂O₃) film on a silicon carbide (SiC) substrate or a silicon (Si) substrate for solar batteries, which are, for example, approximately 4 inches (100 mm) in diameter, instead of a common wafer of 12 inches (300 mm) in size. Further, consideration has been given as well to a process of manufacturing a light-emitting diode (LED) device by depositing a gallium nitride (GaN) film on a wafer by metal organic chemical vapor deposition (MO-CVD) using, for example, a sapphire substrate of 100 mm in outside diameter as the wafer.

However, performing this process with these substrates loaded in multiple stages in a wafer boat causes a relative increase in apparatus cost because these substrates are smaller in size than 12 inch wafers. Further, the vertical dimension of the wafer boat (heat treatment apparatus) is limited by, for example, the ceiling surface of a clean room. Therefore, it is difficult to increase the number of substrates to be loaded into the wafer boat (the number of slots) in order to reduce the apparatus cost.

According to an aspect of the present invention, a vertical heat treatment apparatus is provided that improves the efficiency of use of a process gas in performing heat treatment in a reaction tube by feeding multiple substrates loaded in stages in a substrate holder with the process gas from their sides.

In the following, a description is given of a vertical heat treatment apparatus according to an embodiment of the present invention, which is suitable for improving the efficiency of use.

### Embodiment

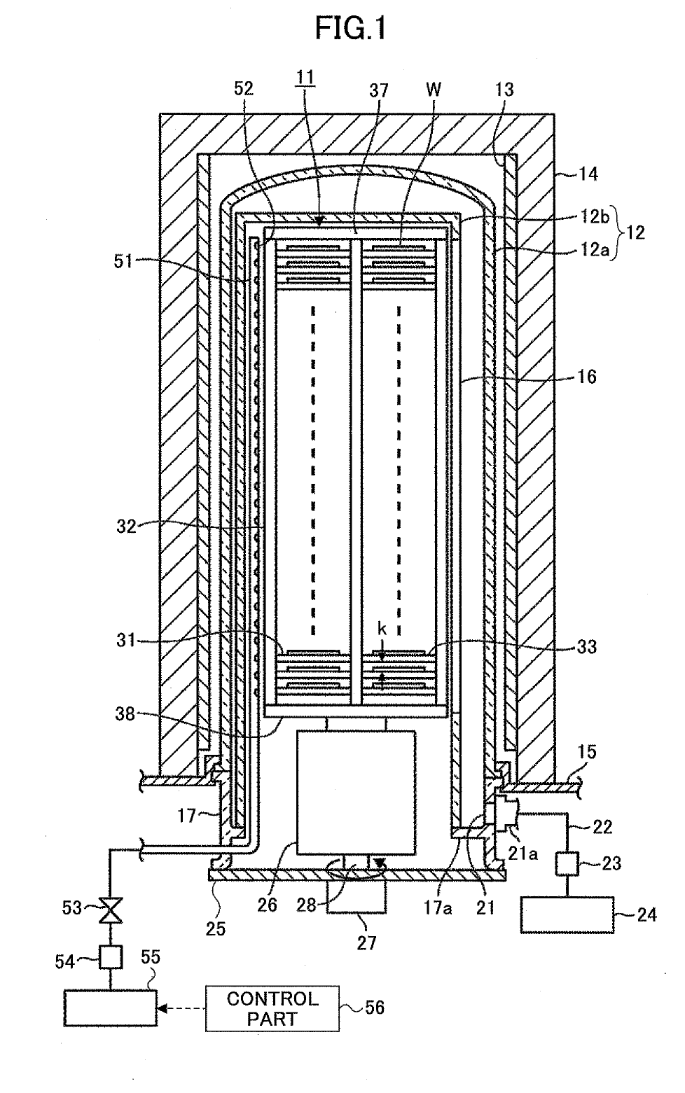

A description is given, with reference to FIG. 1 through FIG. 3, of a vertical heat treatment apparatus according to this embodiment. This vertical heat treatment apparatus includes a wafer boat 11 for loading wafers W in multiple stages and a reaction tube 12 for accommodating the wafer boat 11 inside and performing a film deposition process on the wafers W. The wafer boat 11 is an example of a substrate holder, and is formed of, for example, quartz. The reaction tube 12 is formed of, for example, quartz. In this example, the wafers W are formed of silicon (Si), and have a size of 4 inches (100 mm) in diameter and 0.75 mm in thickness. A heating furnace body 14 is provided outside the reaction tube 12. The heating furnace body 14 has a heater 13, which is an example of a heating part, provided circumferentially on its inner wall surface. The reaction tube 12 and the heating furnace body 14 have their respective lower end portions circumferentially supported by a horizontally extending support part 15.

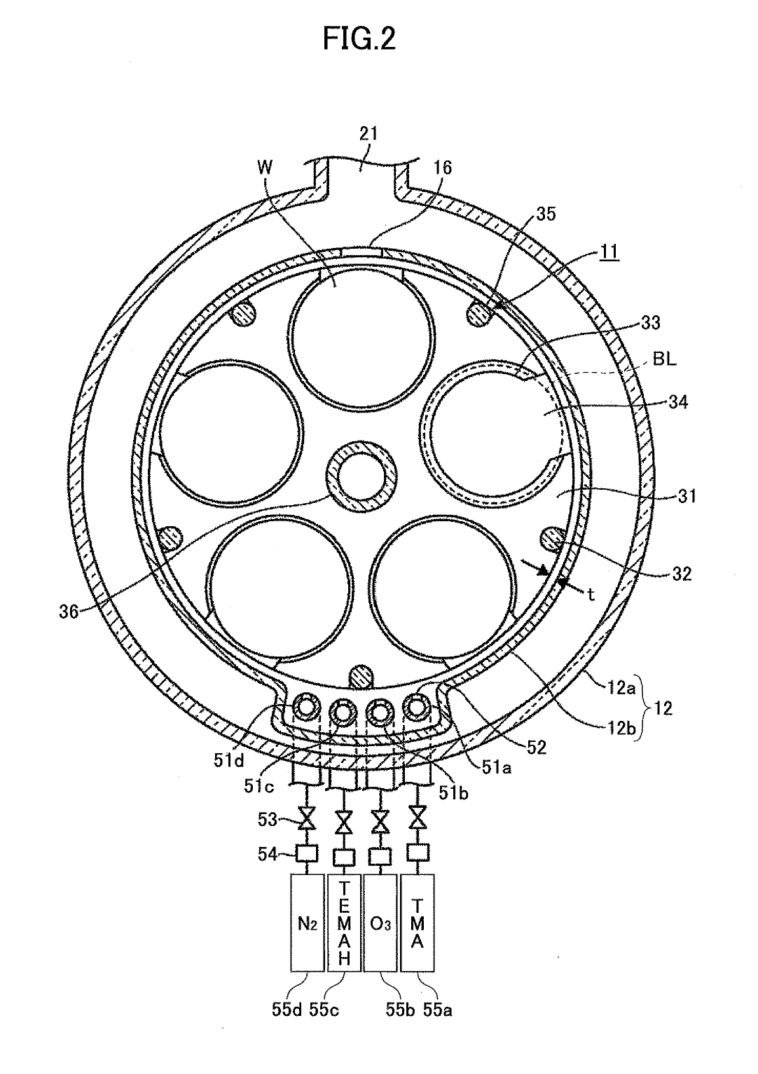

The reaction tube 12 has a double-tube structure of an outer tube 12a and an inner tube 12b contained in the outer tube 12a. Each of the outer tube 12a and the inner tube 12b is formed to be open on the bottom side. The outer tube 12a is an example of a first reaction tube, and the inner tube 12b is an example of a second reaction tube. The inner tube 12b has a horizontal ceiling surface. The outer tube 12a has a ceiling surface curved outward to substantially define a cylindrical shape. The inner tube 12b has a side surface curved outward along a lengthwise direction of the inner tube 12b on one end side, so that gas injectors 51 to be described below, which form a gas feed part, are contained in this outward curved portion of the inner tube 12b. Further, as illustrated in FIG. 2 as well, a slit-shaped exhaust opening 16 is formed in the lengthwise direction of the inner tube 12b in a portion of the inner tube 12b which portion faces the region where the gas injectors 51 are accommodated in the inner tube 12b. That is, the exhaust opening 16 is formed at a position opposite to the gas injectors 51 (gas ejection openings 52) relative to the center of the reaction tube 12.

Process gases fed from the gas injectors 51 into the inner tube 12b are discharged through this exhaust opening 16 to a region between the inner tube 12b and the outer tube 12a. Each of the outer tube 12a and the inner tube 12b has its lower end formed into a flange shape and is supported from the bottom side in an airtight manner by a flange part 17, which has a substantially cylindrical shape open at an upper and a lower end. That is, the outer tube 12a is hermetically supported by an upper end surface of the flange part 17, and the inner tube 12b is hermetically supported by a projection part 17a that horizontally projects inward from the inner wall surface of the flange part 17. The inner tube 12b is, for example, 330 mm in inside diameter.

An exhaust opening 21 is so formed in the sidewall of the flange part 17 as to communicate with the region between the inner tube 12b and the outer tube 12a. This exhaust opening 21 connects to an evacuation passage 22 via an evacuation port 21a. A vacuum pump 24 is connected to the evacuation passage 22 via a pressure control part 23 such as a butterfly valve. A lid body 25 having a substantial disk shape is provided under the flange part 17 so that the peripheral edge portion of the lid body 25 is circumferentially in hermetic contact with a flange surface that is the lower end portion of the flange part 17. The lid body 25 is configured to move upward and downward with the wafer boat 11 with an elevation mechanism such as a boat elevator (not graphically illustrated).

Referring to FIG. 1, a heat insulator 26 is cylindrically formed between the wafer boat 11 and the lid part 25. A motor 27 is an example of a rotation mechanism for causing the wafer boat 11 and the heat insulator 26 to rotate on a vertical axis. Further, a rotating shaft 28 penetrates through the lid body 25 in an airtight manner to connect the motor 27 to the wafer boat 11 and the heat insulator 26.

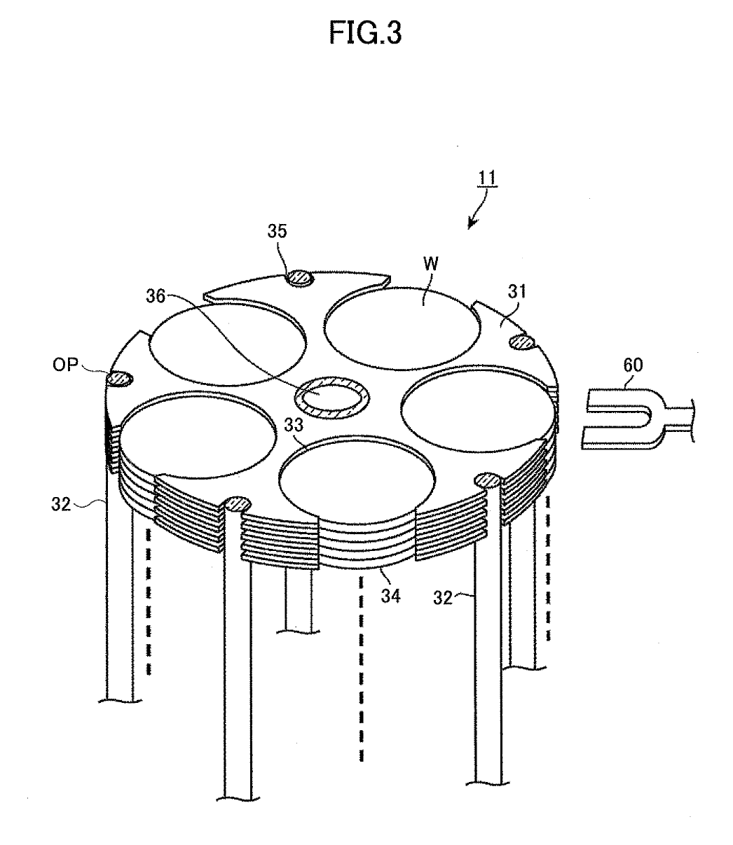

Next, a description is given in detail of the wafer boat 11. As illustrated in FIG. 2 and FIG. 3, this wafer boat 11 has multiple circular holder plates 31 of, for example, 300 mm in diameter in order to circumferentially place multiple wafers W, for example, five wafers W, in a horizontal position, and has multiple vertically extending support rods 32 that support these holder plates 31 from their peripheral sides at multiple points in order to stack the multiple holder plates 31, for example, 150 holder plates 31 in this case, at intervals in multiple stages (layers). In this wafer boat 11, the clearance between holder plates 31 adjacent to each other (the distance between the upper surface of a first holder plate 31 and the lower surface of a second holder plate 31 immediately above and opposite the first holder plate 31) k (FIG. 1) is, for example, 8 mm.

In this example, the five support rods 32 are arranged at equal intervals. As illustrated in FIG. 2, the support rods 32 are so disposed as to not project outward (toward the inner tube 12b) relative to the outer edges (peripheries) of the holder plates 31. Specifically, in the peripheral portion of each of the holder plates 31, multiple concavities 35, for example, five concavities 35, curved toward the center of the holder plate 31 are so formed as to accommodate the support rods 32. The support rods 32 are vertically accommodated in (fit into) the concavities 35 of the holder plates 31 and welded to the holder plates 31. That is, the support rods 32 support the holder plate 31 by penetrating through the peripheral edge portions of the holder plates 31.

The clearance t between the outer edges of the holder plates 31 and the inner wall surface of the inner tube 12b as illustrated in FIG. 2 is smaller than the clearance k between holder plates 31, and is, for example, 5 mm. Referring to FIG. 2 and FIG. 3, a column part 36 penetrates through the center portions of the holder plates 31 to support the holder plates 31. Further, as illustrated in FIG. 1, a disk-shaped top plate 37 and a disk-shaped bottom plate 38 are provided at the upper end and the lower end, respectively, of the wafer boat 11. In FIG. 3, the top plate 37 and the bottom plate 38 are omitted, and part of the wafer boat 11 is graphically illustrated on a larger scale.

In each of the holder plates 31, substrate placement regions 33 for placing the wafers W are arranged so that the peripheral portions of the wafers W on the outer edge side of the holder plate 31 are positioned on the outer edge of the holder plate 31. Accordingly, when viewed in a radial direction of the reaction tube 12, the outer edges of the wafers W and the peripheral surfaces of the support rods 32 are aligned on the border line of the holder plate 31 (that is, the circumference of a circle concentric with and equal in diameter to the holder plate 31). That is, according to an aspect of this embodiment, the radial position of the outer edge of the holder plate 31 is the same as the radial positions of the peripheries (outside positions OP in FIG. 3) of the support rods 32 relative to the center of the reaction tube 12. In other words, the outer edge of the holder plate 31 and the outside positions OP of the support rods 32 are at the same distance (equally distant) from the center of the reaction tube 12 in the radial direction of the reaction tube 12. Here, the outside positions OP of the support rods 32 are the positions of the peripheries of the support rods 32 farthest or most distant from the center of the reaction tube 12 in its radial direction.

Further, the substrate placement regions 33 are formed so that the surfaces of the wafers W placed in the substrate placement regions 33 are vertically at the same position as the surface of the holder plate 31, that is, the upper surfaces of the wafers W and the upper surface of the holder plate 31 are in the same plane. Specifically, the distance between the surfaces of the substrate placement regions 33 and the lower surface of the holder plate 31 that faces the surfaces of the substrate placement regions 33 is determined to be, for example, 8 mm to 10 mm in accordance with the thickness (for example, 0.5 mm to 2 mm) of the wafers W accommodated in these substrate placement regions 33.

In each of the holder plates 31, a cut 34 is formed in the center part of each substrate placement region 33 and its region on the peripheral side of the holder plate 31 relative to the center part in order to have the wafers W transferred to and from an external transfer arm 60 schematically illustrated in FIG. 3. Thus, the wafers W have their peripheral edge portions supported from the bottom side in the substrate placement regions 33. In FIG. 1, the positions of the wafers W are schematically illustrated. Further, in FIG. 2, the outline of one of the wafers W is indicated by a broken line BL in order to graphically illustrate the cut 34.

At the time of placing the wafers W in the wafer boat 11, with the wafer boat 11 moved downward to a position below the reaction tube 12, the transfer arm 60 supporting a wafer W moves downward from above the substrate placement region 33 to pass through the cut 34 to below the substrate placement region 33, so that the wafer W is placed in the substrate placement region 33. Further, the wafer boat 11 is caused to rotate on the vertical axis so that another substrate placement region 33 faces the transfer arm 60 side, and a wafer W is placed in the substrate placement region 33 in the same manner. After thus placing five wafers W on the holder plate 31 by causing the wafer boat 11 to intermittently rotate, the transfer arm 60 is caused to move, for example, downward, so that five wafers W are placed on the holder plate 31 positioned below the previous holder plate 31 in the same manner. At the time of unloading the wafers W from the wafer boat 11, the wafer boat 11 and the transfer arm 60 are driven in reverse order to that at the time of placing the wafers W in the wafer boat 11. Transfer arms 60 may be arranged in multiple stages to have multiple wafers W transferred to and from the wafer boat 11 at the same time.

The gas injectors 51 are formed of, for example, quartz, and are disposed along a lengthwise direction of the wafer boat 11. In the sidewalls of the gas injectors 51, the gas ejection openings 52 are so formed at multiple positions in a vertical direction as to face the wafer boat 11 side. These gas ejection openings 52 are so arranged as to correspond to the vertical positions of the wafers W accommodated in the wafer boat 11. That is, each of the gas ejection openings 52 is so positioned as to correspond to a space between one holder plate 31 and another holder plate 31 (or the top plate 37) immediately above and opposite the one holder plate 31. The gas injectors 51 are inserted into the inner tube 12b through the sidewall of the flange part 17 on one end side, and are connected through valves 53 and flow rate control parts 54 to gas reserve sources 55 where process gases are reserved on the other end side. As illustrated in FIG. 2, the multiple gas injectors 51, for example, four gas injectors 51, are provided side by side. In the following, these four gas injectors 51 are referred to as gas injectors 51a, 51b, 51c, and 51d, respectively, and the corresponding gas reserve sources 55 are also referred to as gas reserve sources 55a, 55b, 55c, and 55d, respectively.

These gas injectors 51a through 51d are connected to the gas reserve sources 55a through 55d of trimethyl aluminum (TMA) gas, which is a first process gas, ozone (O₃) gas, which is a second process gas, tetrakis-ethyl-methyl-amino-hafnium (TEMAH) gas, which is a third process gas, and nitrogen (N₂) gas, which is a purge gas, respectively. The gas ejection openings 52 of the gas injectors 51 are oriented to the exhaust opening 16. However, if the support rods 32 may affect the uniformity of film thickness, the gas ejection openings 52 of the gas injectors 51 may not be oriented to the exhaust opening 16, and specifically, may be oriented to positions slightly away from the exhaust opening 16 horizontally.

This vertical heat treatment apparatus includes a control part 56 (FIG. 1) formed of a computer configured to output control signals to control the operation of the overall apparatus. The control part 56 includes a memory that contains a program for performing a film deposition process to be described below. This program is installed in the control part 56 from a storage part that is a storage medium such as a hard disk, a compact disk, a magneto-optical disk, a memory card, or a flexible disk.

Next, a description is given of operations of the vertical heat treatment apparatus according to this embodiment. First, the wafer boat 11 is moved downward to below the reaction tube 12. While causing the wafer boat 11 to intermittently rotate as described above, five wafers W are placed on each of the holding plates 31 with the transfer arm 60. Then, the wafer boat 11 in which, for example, 750 (5×150) wafers W are placed is inserted into the reaction tube 12, and the lower surface (flange surface) of the flange part 17 and the upper surface of the lid body 25 are caused to come into hermetic contact.

Next, the reaction tube 12 is evacuated to a vacuum by evacuating the atmosphere (gas atmosphere) inside the reaction tube 12 with the vacuum pump 24, and while causing the wafer boat 11 to rotate on the vertical axis, heating is performed with the heater 13 so that the wafers W in the wafer boat 11 become, for example, 300° C. in temperature. Then, while causing the pressure inside the reaction tube 12 to be controlled to a process pressure with the pressure control part 23, TMA gas is fed into the reaction tube 12 from the gas injector 51a.

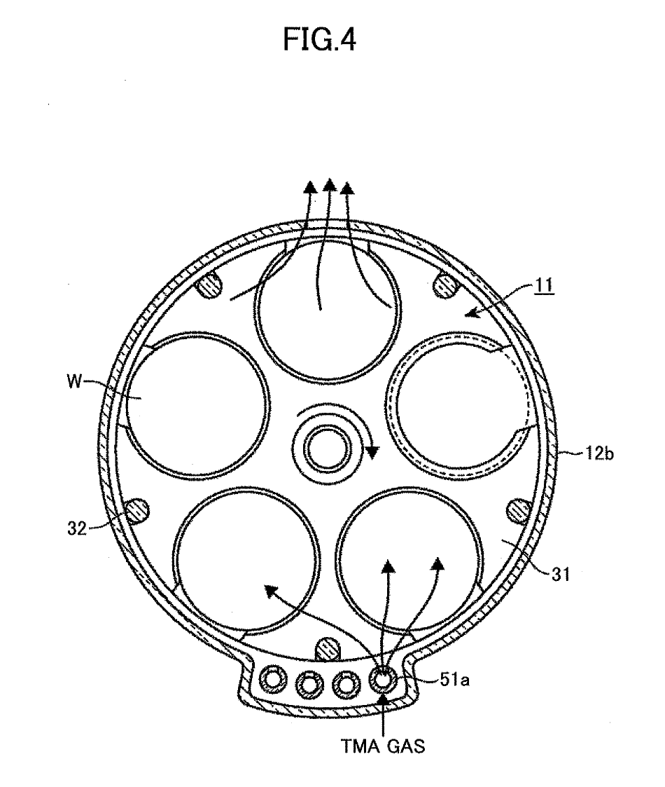

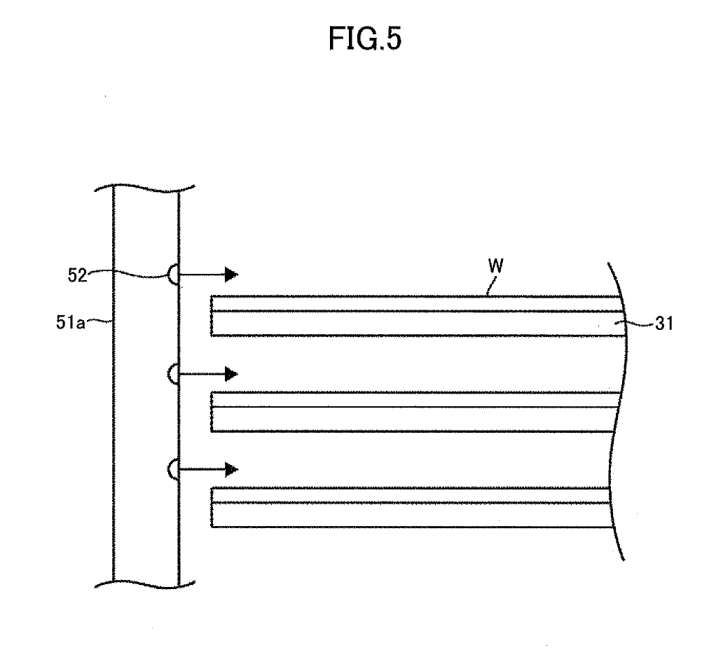

At this point, the gas ejection openings 52 are positioned beside the wafers W, and the regions between the holder plates 31 of the wafer boat 11 are wider than the region between the outer edges of the holder plates 31 and the inner wall surface of the inner tube 12b. Therefore, as illustrated in FIG. 4, the TMA gas fed into the reaction tube 12 tends to flow through the regions between the holder plates 31, which are wider than the narrow area between the outer edges of the holder plates 31 of the wafer boat 11 and the inner wall surface of the inner tube 12b. That is, as illustrated in FIG. 5, the upward and the downward diffusion of the TMA gas ejected from the gas ejection openings 52 are controlled by the holder plates 31. Accordingly, the TMA gas flows horizontally in a laminar flow on and above the wafers W toward the exhaust opening 16. The TMA gas thus comes into contact with the wafers W, and the atomic layer or the molecular layer of the TMA gas adsorbs to the surfaces of the wafers W. Then, part of the TMA gas that has not adsorbed to the wafers W is discharged outside the reaction tube 12 through the exhaust openings 16 and 21.

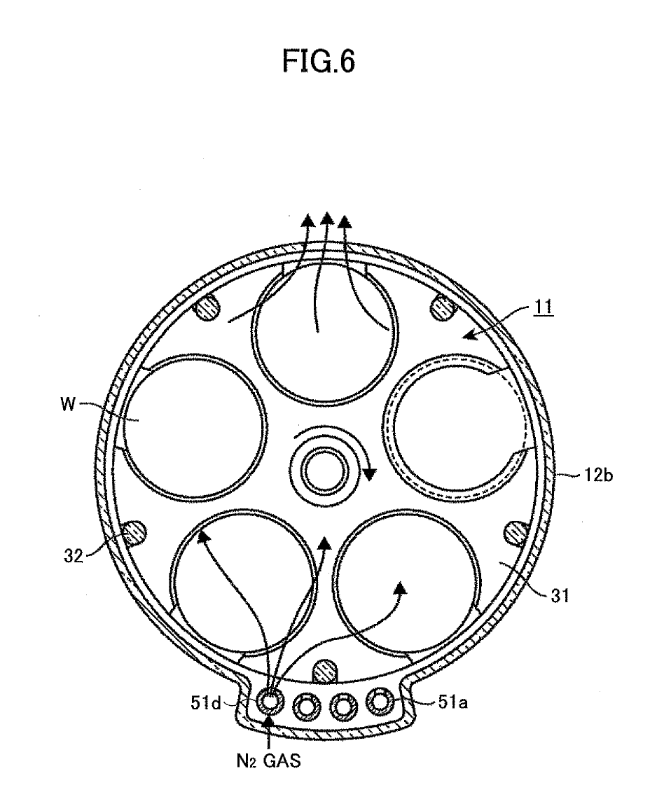

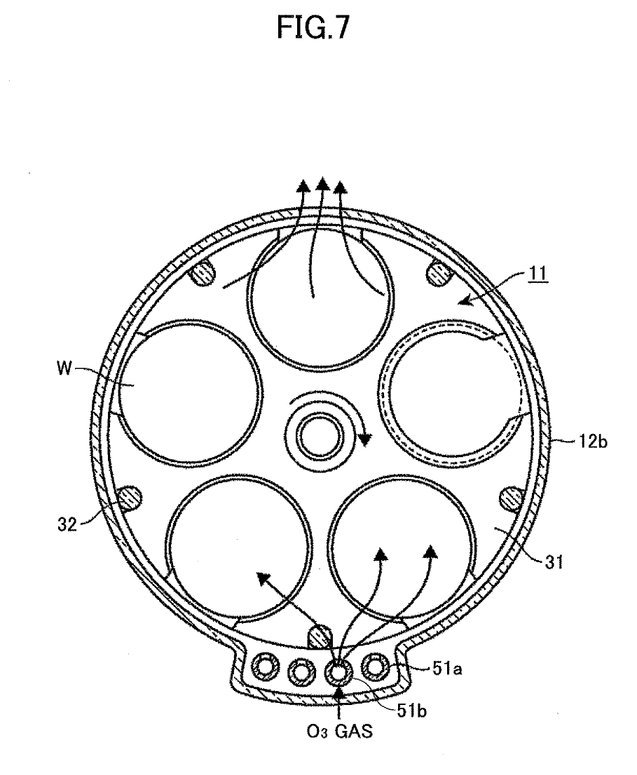

Next, the feeding of the TMA gas is stopped, and as illustrated in FIG. 6, N2 gas is fed into the reaction tube 12 from the gas injector 51d to replace the atmosphere inside the reaction tube 12. Next, the feeding of the N2 gas is stopped, and as illustrated in FIG. 7, the O₃ gas is fed into the reaction tube 12 from the gas injector 51b. This O₃ gas also flows in a laminar flow from the gas ejection openings 52 toward the wafers W to oxidize the TMA gas component adsorbed to the wafers W and generate a reaction product of alumina (Al₂O₃). Then, after stopping the feeding of the O₃ gas, the atmosphere of the reaction tube 12 is replaced with N₂ gas. The feed cycle of feeding TMA gas, N₂ gas, O₃ gas, and N₂ gas in this order is repeated multiple times, so that layers of the above-described reaction product are stacked.

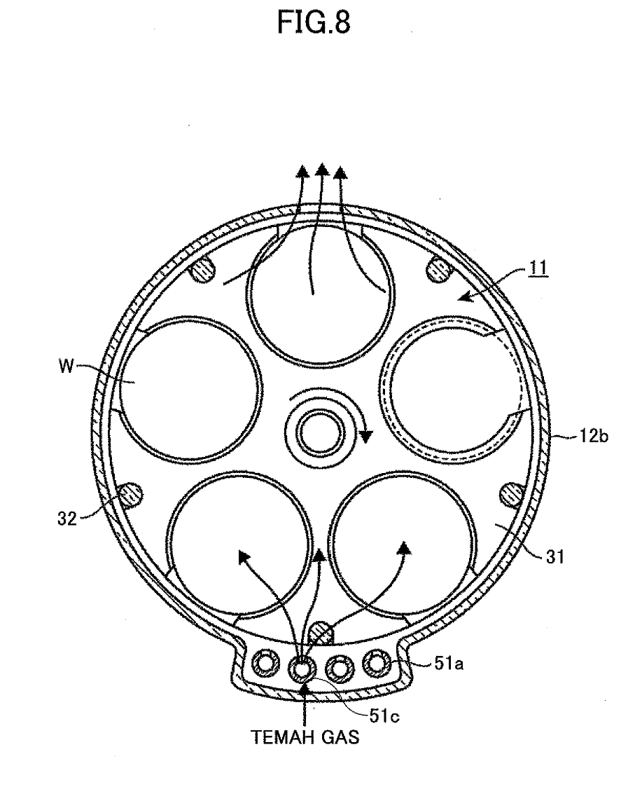

Thereafter, as illustrated in FIG. 8, TEMAH gas is fed in a laminar flow into the reaction tube 12 in the same manner, so that the TEMAH gas is caused to adsorb to the surfaces of the wafers W. Thereafter, N₂ gas and O₃ gas are fed in this order, so that a reaction product of hafnium oxide (HfO₂) is formed on the surfaces of the wafers W. Then, the feed cycle of feeding these gases in order is repeated multiple times, so that layers of the reaction product of hafnium oxide are stacked to form a thin film. Thereafter, the atmosphere inside the reaction tube 12 is returned to an ambient atmosphere. Thereafter, the wafer boat 11 is moved downward, and the wafers W are extracted with the transfer arm 60.

According to this embodiment, in a vertical heat treatment apparatus that performs heat treatment on substrates held in a substrate holder by ejecting process gases from gas ejection openings formed at vertical positions corresponding to the substrates, multiple circular holder plates are stacked in layers to hold multiple substrates on each holder plate, and support rods supporting the peripheral edge portions of these holder plates are so provided as to not project from the outer edges of the holder plates. This makes it possible to reduce the gap between the holder plates and a reaction tube. As a result, it is possible to reduce the amount of a process gas that passes outside the holder plates and therefore does not contribute to a process. Therefore, it is possible to make effective use of a process gas, that is, it is possible to improve the efficiency of use of a process gas. Further, multiple substrates are placed on each of the holder plates. Therefore, compared with the case of placing one substrate on each holder plate, it is possible to reduce the footprint of the apparatus per substrate. Therefore, it is possible to reduce the cost of the apparatus.

More specifically, according to this embodiment, in the vertical heat treatment apparatus that performs heat treatment on the wafers W held in the wafer boat 11 by ejecting process gases from the gas ejection openings 52 formed at vertical positions corresponding to the wafers W, the circular holder plates 31 are stacked in layers to hold multiple wafers W on each holder plate 31, and the support rods 32 supporting the peripheral edge portions of these holder plates 31 are so provided as to not project from the outer edges of the holder plates 31. Accordingly, it is possible to reduce the gap between the holder plates 31 and the reaction tube 12. Therefore, it is possible to reduce the amount of a process gas that passes outside the holder plates 31 and therefore does not contribute to a process. Therefore, it is possible to make effective use of a process gas, that is, it is possible to feed a process gas onto the surfaces of the wafers W with efficiency. Further, making effective use of a process gas allows prompt deposition of a thin film. Therefore, it is possible to improve productivity. Further, since each of the wafers W is fed with a sufficient amount of a process gas, it is possible to obtain a thin film of uniform thickness in the plane of the wafer W. Further, even if depressions such as grooves or holes are formed on the surface of the wafer W, the process gas spreads inside the depressions. Therefore, it is possible to obtain a thin film of a high coverage characteristic without feeding a large amount of a process gas. Further, the holder plates 31 support the outer edge regions of the wafers W, and unlike plate-shaped holder plates, allow film deposition on the backsides of the wafers W. Accordingly, it is possible to prevent the warpage of the wafers W in the thickness directions (vertical directions).

Since multiple wafers W are placed on each of the holder plates 31, compared with the case of placing one wafer W on each holder plate 31, it is possible to reduce the footprint of the apparatus per wafer W. Therefore, it is possible to reduce the cost of the apparatus. In general, the conventional apparatus has slots each containing a single wafer on a holder plate provided in multiple stages. According to this embodiment, the number of wafers W placed on each holder plate 31 is, for example, five. According to the apparatus configuration of this embodiment, the throughput of the apparatus is quintupled, while the footprint of the apparatus (the outside diameter of the reaction tube 12) is no more than approximately tripled. Therefore, even if the vertical dimension of the vertical heat treatment apparatus (the wafer boat 11) is limited by, for example, the ceiling surface of a clean room, it is possible to increase the number of wafers W that may be processed with the vertical heat treatment apparatus. Therefore, it is possible to reduce the cost of the apparatus for processing a single wafer W. That is, according to this embodiment, it is possible to cause an approximately severalfold increase in the number of wafers W that may be processed at a time. Further; in this example, five wafers W having a size of 100 mm in diameter are circumferentially arranged on each of the holder plates 31. Therefore, it is possible to use apparatuses (the reaction tube 12 and the heating furnace body 14) for common 300 mm wafers, and the process conditions and the apparatus operating conditions that have been established for 300 mm wafers may be used as they are.

In thus making effective use of a process gas, the clearance t between the outer edges of the holder plates 31 and the inner wall surface of the inner tube 12b is such a small value that allows the wafer boat 11 to rotate inside the inner tube 12b, and is specifically 3 mm to 8 mm, and preferably, 5 mm to 8 mm. Accordingly, when viewed in a radial direction of the reaction tube 12, the outside positions OP (FIG. 3) of the support rods 32 may be located inside relative to the outer edges of the holder plates 31, or the support rods 32 may project relative to the outer edges of the holder plates 31 if the projection is so small as to allow the effects of this embodiment to be produced. Specifically, the support rods 32 may be at or inside positions where the support rods 32 project outward 3 mm relative to the outer edges of the holder plates 31.

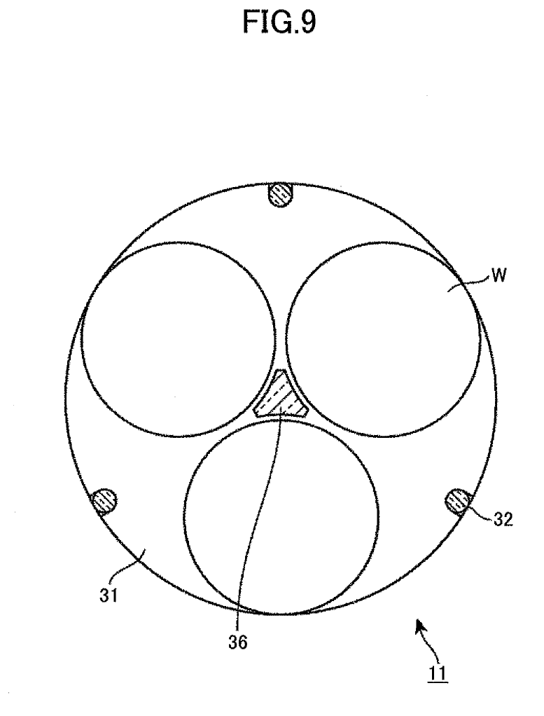

In the above-described example, five wafers W are placed on each of the holder plates 31, while three wafers W may be placed on each of the holder plates 31 as illustrated in FIG. 9. In this case, compared with the case of stacking slots each containing a single wafer in multiple stages, the throughput of the apparatus is tripled, while the footprint of the apparatus is no more than approximately 2.2 times. Therefore, like in the above-described example, it is possible to reduce the cost of the apparatus. Further, the number of wafers W placed per holder plate 31 may be two or more. In the case of placing two wafers W on each of the holder plates 31 as well, it is possible to make effective use of a process gas the same as in the above-described example.

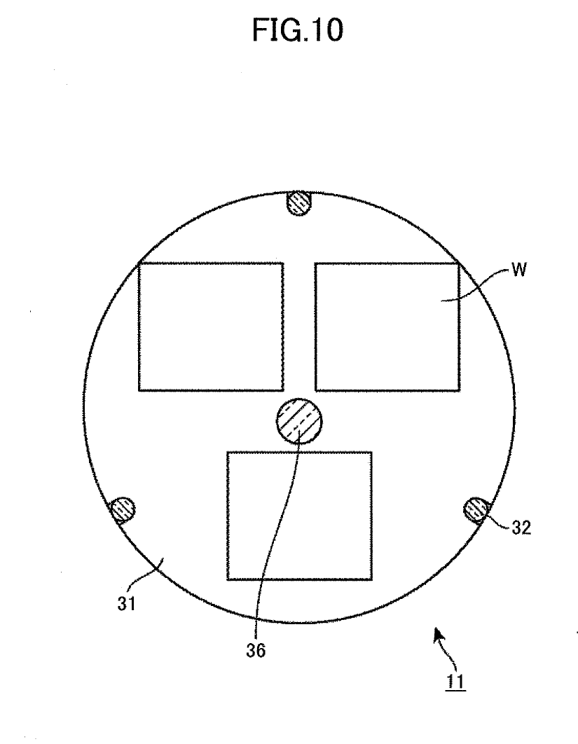

Further, as the wafers W, in addition to those of 100 mm in size as described above, common-size wafers W of 300 mm in diameter may be used. Furthermore, even when the wafers W are, for example, angular wafers of polysilicon for solar batteries, it is possible to form a laminar flow of gas between the holder plates 31 by forming the substrate placement regions 33 corresponding to the outer shape of the wafers W in the holder plates 31. Therefore, it is possible to perform a uniform process irrespective of the outer shape of the wafers W, and it is possible to make effective use of a process gas and reduce the cost of the apparatus. FIG. 10 illustrates a case where such angular wafers W, for example, three angular wafers W, are placed on the holder plate 31.

Further, in the above-described example, a thin film is deposited using atomic layer deposition (ALD), according to which a process gas for an atomic layer or a molecular layer is caused to adsorb to the surfaces of the wafers W, and then this process gas is oxidized to form a reaction product. On the other hand, a thin film may also be formed by chemical vapor deposition (CVD). In this case, for example, the above-described TMA gas and O₃ gas are fed into the reaction tube 12 at the same time.

Further, the vertical heat treatment apparatus of this embodiment is applied to a film deposition method for depositing a thin film on the surfaces of the wafers W. On the other hand, the vertical heat treatment apparatus of this embodiment may also be applied to the case of performing thermal oxidation of silicon (Si) at the surfaces of the wafers W by feeding, for example, O₂ gas or H₂O gas as a process gas.

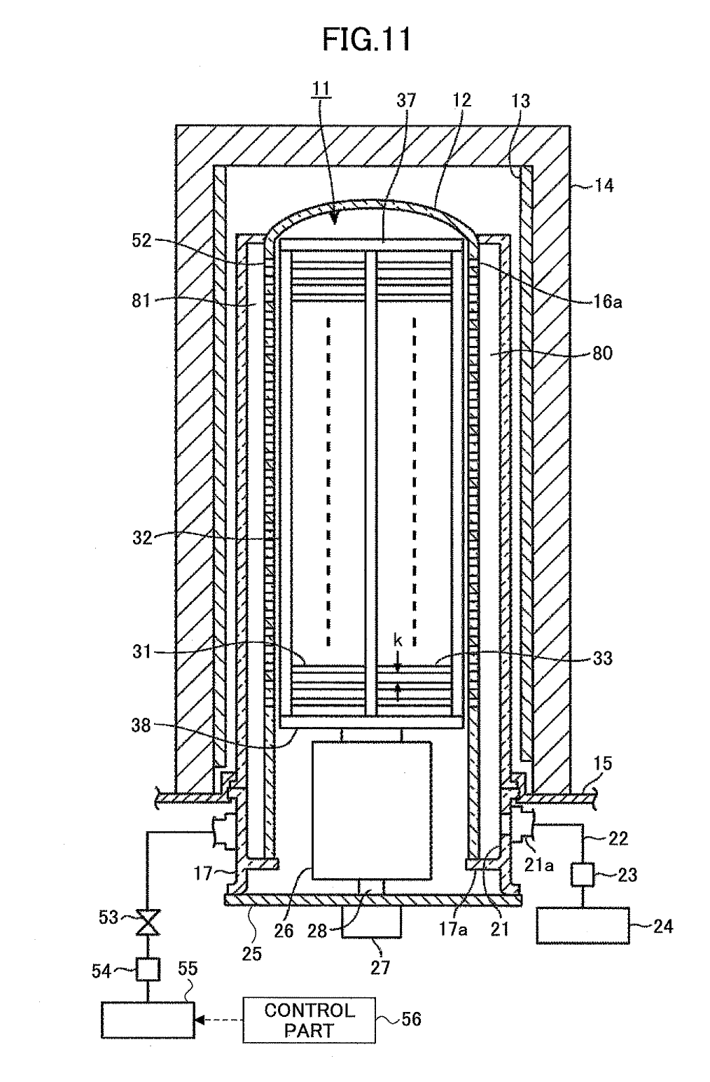

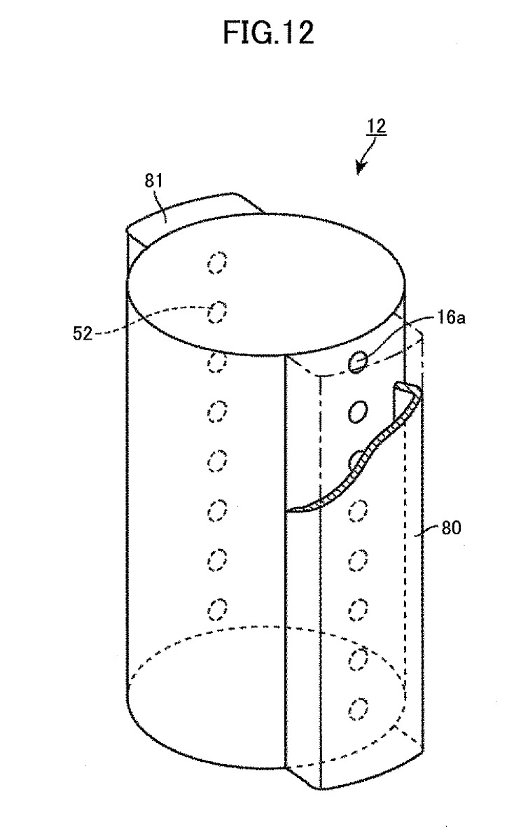

Further, the gas ejection openings 52 may be formed into a slit shape in the lengthwise direction of the wafer boat 11. Further, instead of the double-tube structure of the reaction tube 12, a duct-shaped gas feed part and a duct-shaped exhaust part each elongated in the lengthwise direction of the wafer boat 11 may be provided on the exterior of the reaction tube 12 in an airtight manner, and the gas ejection openings 52 and exhaust openings 16a may be formed at multiple positions in a vertical direction in the reaction tube 12 on opposite sides so as to communicate with the gas feed part and the exhaust part, respectively. FIG. 11 and FIG. 12 illustrate such a configuration where an exhaust duct 80 and a gas feed part 81 are hermetically provided on the exterior of the reaction tube 12. In FIG. 12, part of the exhaust duct 80 is cut out to illustrate some of the exhaust openings 16a inside.

Furthermore, the cut 34 is formed in each of the holder plates 31 to have the wafers W transferred to and from the wafer boat 11. On the other hand, for example, through holes may be formed at, for example, three points in each of the substrate placement regions 33, and a transfer mechanism having three pins so provided as to be movable upward and downward, which is not graphically illustrated, may be provided below the wafer boat 11. In this case, for example, the wafer boat 11 is positioned below the reaction tube 12, and when a wafer W is transferred to a position above the substrate placement region 33 with the transfer arm 60, the three pins move upward from below the wafer boat 11 through the through holes of the holder plates 31 to receive the wafer W from the transfer arm 60. Then, the transfer arm 60 is retracted and the pins are moved downward, so that the wafer W is placed in the substrate placement region 33. Thereafter, the wafers W are successively placed on the holder plates 31 below. At the time of extracting the wafers W from the wafer boat 11, the wafers W are successively transferred to the transfer arm 60 with those on a lower side in the wafer boat 11 first.

In the above-described examples, after depositing a reaction product of alumina and a reaction product of hafnium oxide in layers on the surfaces of the wafers W, these reaction products may be further deposited in layers as required to form a thin film of a laminated structure. Further, the present invention may also be applied to a process for manufacturing an LED device by depositing a gallium nitride (GaN) film on the wafers W by MO-CVD using sapphire substrates of, for example, 100 mm in outside diameter as the wafers W.

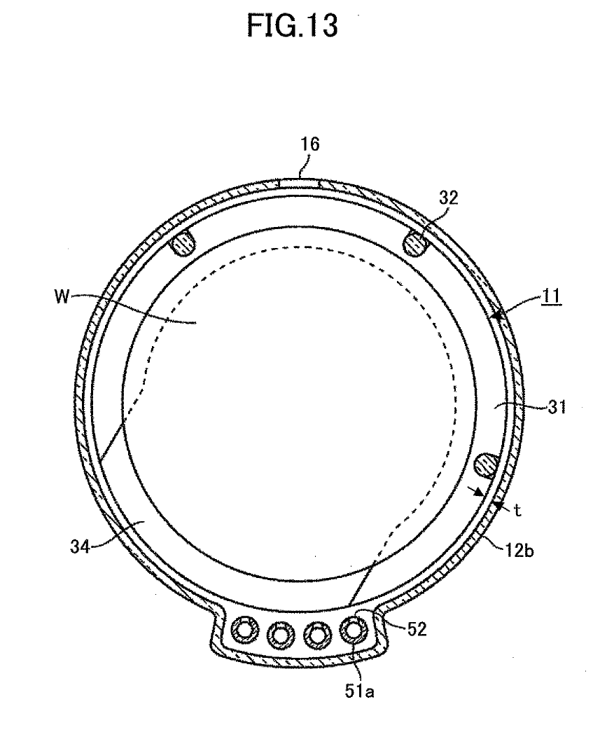

Further, in the above-described examples, multiple wafers W are placed on each of the holder plates 31, while the wafers W may be placed one on each of the holder plates 31 as illustrated in FIG. 13. Specifically, the substrate placement region 33 of the holder plate 31 is formed concentrically with the wafer W. Further, the outer edge portion of the holder plate 31 extends toward the inner tube 12b relative to the peripheral portion of the wafer W, so that the clearance t between the outer edge of the holder plate 31 and the inner wall surface of the inner tube 12b is smaller than the clearance k between holder plates 31 adjacent to each other the same as in the above-described examples. The support rods 32 are so arranged as to allow the wafer W to be transferred to and from the holder plate 31. In this case as well, a process gas tends to flow more through the regions between the holder plates 31 than through the gap region between the holder plates 31 and the inner tube 12b. Therefore, the process gas is effectively used. In FIG. 13, a graphical illustration of the outer tube 12a (for example, FIG. 2) is omitted.

According to an embodiment of the present invention, it is possible to reduce the gap between a holder plate and a reaction tube and to reduce the amount of a process gas passing outside the holder plate, so that it is possible to improve the efficiency of use of the process gas.

Additional advantages and modifications will readily occur to those skilled in the art. Therefore, the invention in its broader aspects is not limited to the specific details and representative embodiment shown and described herein. Accordingly, various modifications may be made without departing from the sprit or scope of the general inventive concept as defined by the appended claims and their equivalents.

What is claimed is:

1. A vertical heat treatment apparatus, comprising:
a vertical reaction tube including a substrate holder and surrounded by a heating part, the substrate holder being configured to hold a plurality of substrates in multiple stages and to perform heat treatment on the substrates; and
a process gas feed part provided in a lengthwise direction of the reaction tube and having a plurality of gas ejection openings formed at vertical positions corresponding to the respective substrates to feed a process gas onto the substrates held in the substrate holder,
wherein the reaction tube has an exhaust opening formed therein at a position opposite to the gas ejection openings relative to a center of the reaction tube, and
the substrate holder includes
a plurality of circular holding plates stacked in layers at intervals and each having a plurality of substrate placement regions formed thereon; and
a plurality of support rods supporting the holding plates, the support rods being provided in a circumferential direction of the holding plates to penetrate through the holding plates with outside positions of the support rods being at a same radial position as outer edges of the holding plates or at a radial position inside the outer edges of the holding plates relative to the center of the reaction tube.

2. The vertical heat treatment apparatus as claimed in claim 1, wherein a clearance between the outer edges of the holder plates and an inner wall surface of the reaction tube is smaller than a clearance between upper surfaces of the substrates supported on a first one of the holding plates and a lower surface of a second one of the holding plates immediately above and opposite the first one of the holding plates.

3. The vertical heat treatment apparatus as claimed in claim 1, wherein a clearance between the outer edges of the holder plates and an inner wall surface of the reaction tube is 8 mm or less.

4. The vertical heat treatment apparatus as claimed in claim 1, wherein outer edges of the substrates in the substrate holder and peripheral surfaces of the support rods are aligned on border lines of the holder plates relative to a radial direction of the reaction tube.

5. The vertical heat treatment apparatus as claimed in claim 1, wherein
the reaction tube includes
a first reaction tube configured to be opened and hermetically closed; and
a second reaction tube provided inside the first reaction tube and accommodating the substrate holder,
the process gas feed part includes a gas injector placed inside the second reaction tube in a lengthwise direction of the substrate holder,
the exhaust opening is formed in the second reaction tube at a position opposite the gas injector, the exhaust opening having a slit shape in a lengthwise direction of the gas injector, and
an evacuation port for evacuating a gas atmosphere in a region between the first reaction tube and the second reaction tube is so provided as to communicate with the region.

6. The vertical heat treatment apparatus as claimed in claim 1, further comprising:
a rotation mechanism configured to cause the substrate holder to rotate on a vertical axis.

7. The vertical heat treatment apparatus as claimed in claim 1, wherein
the process gas feed part includes
a first gas supply part configured to feed a first process gas onto the substrates;
a second gas feed part configured to feed a second process gas reacting with the first process gas onto the substrates;
a third gas feed part configured to feed a purge gas onto the substrates; and
a control part configured to output a control signal so as to cause the first process gas and the second process gas to be fed alternately onto the substrates and to cause the purge gas to be fed onto the substrates to perform gas replacement at a time of switching between the first process gas and the second process gas.

8. A vertical heat treatment apparatus, comprising:
a vertical reaction tube including a substrate holder and surrounded by a heating part, the substrate holder being configured to hold a plurality of substrates in multiple stages and to perform heat treatment on the substrates; and
a process gas feed part provided in a lengthwise direction of the reaction tube and having a plurality of gas ejection openings formed at vertical positions corresponding to the respective substrates to feed a process gas onto the substrates held in the substrate holder,
wherein the reaction tube has an exhaust opening formed therein at a position opposite to the gas ejection openings relative to a center of the reaction tube,
the substrate holder includes
a plurality of circular holding plates stacked in layers at intervals and each having a substrate placement region formed thereon; and
a plurality of support rods supporting the holding plates, the support rods being provided in a circumferential direction of the holding plates to penetrate through the holding plates with outside positions of the support rods being at a same radial position as outer edges of the holding plates or at a radial position inside the outer edges of the holding plates relative to the center of the reaction tube, and
a clearance between the outer edges of the holder plates and an inner wall surface of the reaction tube is smaller than a clearance between an upper surface of the substrate supported on a first one of the holding plates and a lower surface of a second one of the holding plates immediately above and opposite the first one of the holding plates.

9. A vertical heat treatment apparatus, comprising:
a vertical reaction tube including a substrate holder and surrounded by a heating part, the substrate holder being configured to hold a plurality of substrates in multiple stages and to perform heat treatment on the substrates; and
a process gas feed part provided in a lengthwise direction of the reaction tube and having a plurality of gas ejection openings formed at vertical positions corresponding to the respective substrates to feed a process gas onto the substrates held in the substrate holder,
wherein the reaction tube has an exhaust opening formed therein at a position opposite to the gas ejection openings relative to a center of the reaction tube, and
the substrate holder includes
a plurality of circular holding plates stacked in layers at intervals and each having a plurality of substrate placement regions formed thereon; and
a plurality of support rods supporting the holding plates, the support rods being provided in a circumferential direction of the holding plates to penetrate through the holding plates with outside positions of the support rods being at or inside positions 3 mm outward relative to outer edges of the holder plates in a radial direction of the reaction tube.
